(19) United States
(12) Patent Application Publication
(10) Pub. No.: US 2001/0051381 A1
(43) Pub. Date: Dec. 13, 2001

(54) Method for manufacturing a ferroelectric memory

(76) Inventors: Woo-Seok Yang, Ichon-shi (KR); Deuk-Soo Pyun, Ichon-shi (KR)

Correspondence Address: JACOBSON, PRICE, HOLMAN & STERN, PROFESSIONAL LIMITED LIABILITY COMPANY, 400 Seventh Street, N.W., Washington, DC, 20004, US

(21) Appl. No.: 09/867,633

(22) Filed: May 31, 2001

(30) Foreign Application Priority Data
May 31, 2000 (KR) 2000-29686

(51) Int. Cl. H01L 21/00; H01L 21/8234; H01L 21/8244

(52) U.S. Cl. 438/3; 438/238

(57) ABSTRACT

A method for manufacturing a ferroelectric memory device including the steps of forming a polysilicon plug to connect a transistor through an interlayer dielectric (ILD) layer which is formed on a semiconductor substrate incorporating the transistor therein, forming a first conductive layer on the polysilicon plug and the ILD layer, forming a ferroelectric layer on the first conductive layer, carrying out a heat treatment for crystallization of the ferroelectric layer in a presence of an inert gas, forming a second conductive layer on the ferroelectric layer, and patterning the second conductive layer, the ferroelectric layer and the first conductive layer to form a ferroelectric capacitor.

### FIELD OF THE INVENTION

The present invention relates to a method for manufacturing a ferroelectric memory device and, more particularly, to a method for manufacturing a ferroelectric memory device which is capable of preventing a polysilicon plug from being oxidized.

### DESCRIPTION OF THE PRIOR ART

In a semiconductor memory device, by using a ferroelectric material in a capacitor, several studies have been developed to overcome a refresh limit in a conventional dynamic random access memory (DRAM) and to achieve a large capacitance. A ferroelectric random access memory (FeRAM) is one of the nonvolatile memory devices that can store information in a turned-off state and has an operating speed comparable to that of the conventional DRAM.

SrₓBi_{y}Ta₂O₉(SBT) and Pb(ZrₓTi₁₋ₓ)O₃ (PZT) are used as a capacitor dielectric in FeRAM. The ferroelectric material has a dielectric constant being on the order of 10²˜10³ at normal temperatures and has two stabilized remanent polarization states suitable for application to a nonvolatile memory device. The nonvolatile memory device utilizing the ferroelectric material inputs a signal by changing an orientation of polarization to that of an electric field applied thereto and, when the electric field is removed, stores a digital signal “1” or “0” by an orientation of remanent polarization.

In order to take advantage of the above-described FeRAM qualities, it is essential to select a proper material for the bottom and top electrodes and to maintain a proper control of manufacturing processes.

The FeRAM crystallization is brought out when the FeRAM composing elements are diffused into a predetermined position of a crystal grid. For example, in SBT, Sr, Bi, Ta and O, elements are diffused into a predetermined position of a Bi-layered perovskite structure to initiate the FeRAM crystallization. The FeRAM crystallization is carried out over 60 minutes at a temperature ranging from 650° C. to 800° C. to obtain a fast diffusivity of the composing elements and to provide enough time for movement to a predetermined position. The diffusivity is defined as a diffusing material quantity through a unit dimension per unit time.

In a conventional method, the FeRAM crystallization is carried out in the presence of O₂ gas at a temperature ranging from 650° C. to 800° C. to prevent a ferroelectric characteristic deterioration caused by inter-ferroelectric O₂ deficiency. Therefore, during manufacture of the ferroelectric memory device with a polysilicon structure which is adopted in a high density FeRAM device, contact resistance is increased due to oxidation of a polysilicon plug.

### SUMMARY OF THE INVENTION

It is, therefore, an object of the present invention to provide a method for manufacturing a ferroelectric memory device which is capable of preventing a polysilicon plug from being oxidized through the use of a heat treatment during a ferroelectric crystallization process.

In accordance with an aspect of the present invention, there is provided a method for manufacturing a ferroelectric memory device, the method comprising the steps of forming a polysilicon plug to connect a transistor through an interlayer dielectric (ILD) layer which is formed on a semiconductor substrate incorporating the transistor therein, forming a first conductive layer on the polysilicon plug and the ILD layer, forming a ferroelectric layer on the first conductive layer, carrying out a heat treatment for crystallization of the ferroelectric layer in the presence of an inert gas, forming a second conductive layer on the ferroelectric layer, and patterning the second conductive layer, the ferroelectric layer and the first conductive layer to form a ferroelectric capacitor.

### BRIEF DESCRIPTION OF THE DRAWINGS

The above and other objects and features of the present invention will become apparent from the following description of the preferred embodiments given in conjunction with the accompanying drawings, in which:

FIGS. 1 to 5 are cross-sectional views illustrating a method for manufacturing a ferroelectric memory device in accordance with the present invention.

### DETAILED DESCRIPTION OF THE PREFERRED EMBODIMENTS

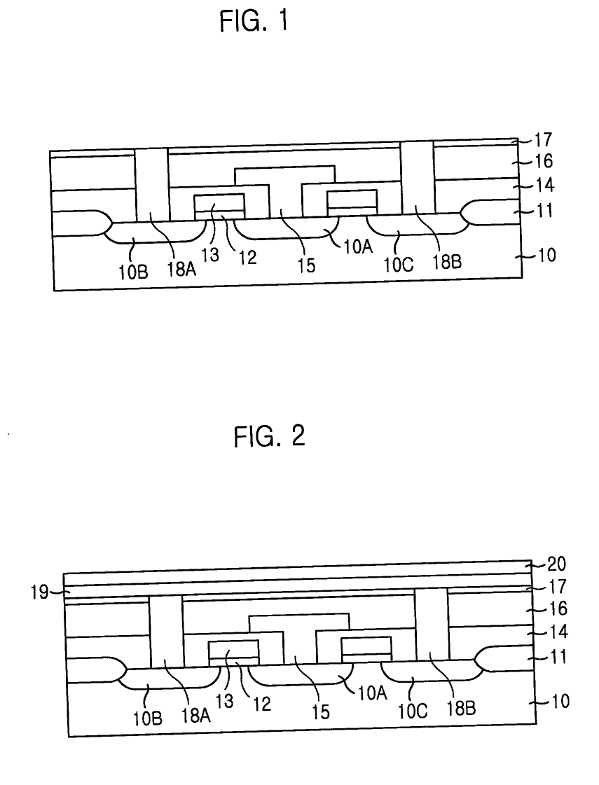

There are provided in FIGS. 1 to 5 cross-sectional views setting forth a method for manufacturing a ferroelectric memory device in accordance with preferred embodiments of the present invention.

In FIG. 1, there is shown a semiconductor substrate 10 provided with transistors. A first interlayer dielectric (ILD) layer 14 is formed on the semiconductor substrate 10. A bit line 15 is formed in a first contact hole in the first ILD layer 14, which is connected to a contact region 10A on the semiconductor substrate 10. Then, a second ILD layer 16 made of, e.g., borophosphor silicate glass (BPSG), and a passivation oxide layer 17 made of, e.g., a high temperature oxide layer, are formed on the bit line 15 and the first ILD layer 14, successively. The passivation oxide layer 17, the second ILD layer 16 and the first ILD layer 14 are selectively etched in such a way that contact regions 10B, 10C on the semiconductor substrate 10 are exposed, thereby obtaining second contact holes. Finally, a polysilicon layer is filled in the contact holes and a portion thereof is removed by using a chemical mechanical polishing (CMP) until the passivation oxide layer 17 is exposed, thereby obtaining polysilicon plugs 18A, 18B which vertically connect a bottom electrode of a capacitor to the contact regions 10B, 10C. Each of reference numerals 11, 12, 13 denotes a field oxide layer, a gate oxide layer and a gate electrode, respectively.

Next, after removing a native oxide on the polysilicon plugs 18A, 18B, which is formed on the plugs during movement of the semiconductor substrate, an adhesion layer 19 is formed on the polysilicon plugs 18A, 18B and the passivation oxide layer 17, as shown in FIG. 2. It is preferable that the adhesion layer 19 be made of Ti and Co. Successively, a silicide may be formed by using a post-heat treatment to decrease contact resistance. A diffusion barrier layer 20 is formed on the adhesion layer 19 to prevent O₂ diffusion, with the diffusion barrier layer 20 being made of TiN, TiAIN and TiSiN.

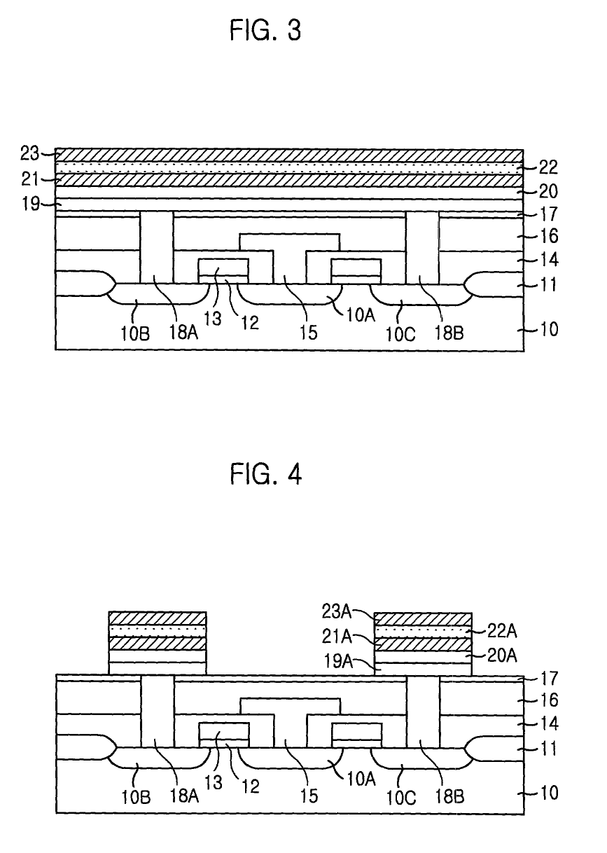

In a following step, shown in FIG. 3, a first conductive layer 21 which will form the bottom electrode of the capacitor is formed on the diffusion barrier layer 20, and a ferroelectric layer 22 is formed on the first conductive layer 21. Thereafter, a heat treatment is carried out in the presence of N₂ gas or an Ar gas at a temperature ranging from 600° C. to 700° C. A post O₂ treatment is then carried out with O₃ or an O₂ remote plasma at a temperature ranging from 200° C. to 400° C. to supply O₂ into the ferroelectric layer, thereby preventing ferroelectric characteristic deterioration due to O₂ deficiency. A second conductive layer 23 is then formed on the ferroelectric layer 22.

The first conductive layer 21 is preferably made of an Ir, IrOₓ and Ir laminated layer, the ferroelectric layer 22 is preferably made of a ferroelectric layer with a bi-layered perovskite, e.g., PZT (Pb(ZrₓTi₁₋ₓ)O₃, with x being 0.4-0.6.), SBT(SrₓBi_{y}Ta₂O₉, with x being 0.7-1.0, and y being 2.0-2.6), SBTN (SrₓBi_{y}(TaᵢNbⱼ)₂O₉, with x, y, i and j being 0.7-1.0, 2.0-2.6, 2.0-0.5 and 0-0.5, respectively) and BLT (Bi₄₋ₓLaₓTi₃O₁₂, with x being 0.6-0.9). The second conductive layer 23 is preferably made of Pt and IrOₓ.

The ferroelectric layer 22 can be formed with various deposition methods such as a metal-organic deposition (MOD), sol-gel, a liquid source mist chemical vapor deposition (LSMCD) and a sputtering and metal organic vapor deposition (MOCVD).

The second conductive layer 23, the ferroelectric layer 22, the first conductive layer 21, the diffusion barrier layer 20 and the adhesive layer 19 are patterned into a top electrode 23A, a ferroelectric film 22A, a bottom electrode 21A, a diffusion barrier 20A and an adhesive film 19A, as shown in FIG. 4. Then, to recover the ferroelectric characteristic which is degraded by an etching during the patterning process, a heat treatment is carried out in the presence of N₂ gas at a temperature ranging from 450° C. to 700° C. for about 30 minutes.

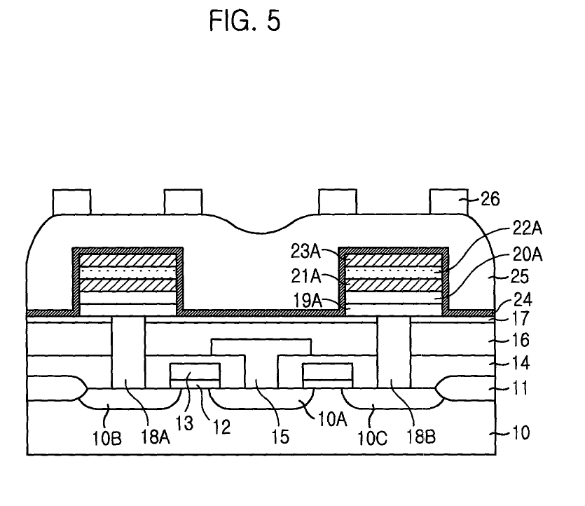

Turning to FIG. 5, a hydrogen diffusion barrier layer 24 is formed with Al₂O₃ for preventing degradation of ferroelectric characteristics due to hydrogen damage which is caused by a hydrogen diffusion in forming an insulating layer to implement a planarization process. A planarized dielectric layer 25 is formed with SiOₓ, spin on glass (SOG) and SiON. A metal wiring 26 can be formed by depositing a TiN anti-reflection layer and an Al layer and patterning the TiN anti-reflection layer and the Al layer.

Meanwhile, the post-O₂ treatment can be omitted when a photoresist pattern is removed by O₂ plasma, with the photoresist layer being used as an etching mask in patterning the second conductive layer 23, the ferroelectric layer 22, the first conductive layer 21, the diffusion barrier layer 20 and the adhesive layer 19. In this case, the O₂ plasma supplies enough O₂ within the ferroelectric layer 22 by forming the planarized dielectric layer 25.

The present invention can carry out the ferroelectric crystallization process without oxidation of the polysilicon plugs. This is achieved by performing the ferroelectric crystallization process in the presence of an inert gas such as N₂ gas or an Ar gas at a temperature ranging from 650° C. to 800° C. At this time, to prevent ferroelectric characteristic deterioration caused by O₂ deficiency, an O₃ or an O₂ remote plasma may be carried out as a post-treatment at a temperature ranging from 650° C. to 800° C. An O₂ atom has a diffusion speed at least 100 times faster than a metal atom, so it is capable of diffusing the O₂ atom into a predetermined position within the ferroelectric crystallization structure at a low temperature. The post-treatment can be omitted when carrying out a photoresist layer-removing process with an O₂ plasma in capacitor patterning process and forming an oxide layer as an interlayer dielectric (ILD) layer on a top portion of the ferroelectric capacitor.

The present invention is capable of preventing the polysilicon plugs from oxidizing and causing increased contact resistance during a FeRAM device manufacturing process, and can also protect the FeRAM from ferroelectric characteristic deterioration.

While the present invention has been described with respect to the particular embodiments, it will be apparent to those skilled in the art that various changes and modifications may be made without departing from the scope of the invention as defined in the following claims.

What is claimed is:

1. A method for manufacturing a ferroelectric memory device, the method comprising steps of:
a) forming a polysilicon plug to connect a transistor through an interlayer dielectric (ILD) layer which is formed on a semiconductor substrate incorporating the transistor therein;
b) forming a first conductive layer on the polysilicon plug and the ILD layer;
c) forming a ferroelectric layer on the first conductive layer;
d) carrying out a heat treatment for crystallization of the ferroelectric layer in a presence of an inert gas;
e) forming a second conductive layer on the ferroelectric layer; and
f) patterning the second conductive layer, the ferroelectric layer and the first conductive layer to form a ferroelectric capacitor.

2. The method of claim 1, between the steps a) and b), further comprising a step of removing a native oxide which is formed on the polysilicon plug during movement of the semiconductor substrate to carry out the step b).

3. The method of claim 1, after the step d) further comprising a step of carrying out a post-O₂ treatment to supply an O₂ gas into the ferroelectric layer.

4. The method of claim 3, wherein the post-O₂ treatment is carried out by using O₃ or an O₂ remote plasma at a temperature ranging from 200° C. to 400° C.

5. The method of claim 1, wherein the step f) includes steps of:
f₁) patterning the second conductive layer, the ferroelectric layer and the first conductive layer into a predetermined configuration by using a photoresist layer as an etching mask; and
f₂) supplying O₂ into the ferroelectric layer by removing a photosensitive layer by an O₂ plasma.

6. The method of claim 1, wherein the step f) further includes a step of forming an oxide layer on the ferroelectric capacitor as an interlayer dielectric (ILD)layer with supplying O₂ into the ferroelectric layer.

7. The method of claim 1, wherein the step d) is carried out at a temperature ranging from 600° C. to 700° C.

8. The method of claim 7, wherein the step d) is carried out in a presence of a N₂ gas or an Ar gas.

9. The method of claim 7, wherein the ferroelectric layer is formed with a material selected from a group consisting of Pb(ZrₓTi_{1-X})O₃, x being 0.4-0.6, SrₓBi_{y}Ta₂O₉, x being 0.7-1.0 and y being 2.0-2.6, SrₓBi_{y} (TaᵢNbⱼ)₂O₉, x, y, i and j being 0.7-1.0, 2.0-2.6, 2.0-0.5 and 0-0.5 respectively, and Bi₄₋ₓLaₓTi₃O₁₂, x being 0.6-0.9.

10. The method of claim 7, after the step f), further comprising a step of carrying out a second heat treatment in a presence of N₂ at a temperature ranging from 450° C. to 700° C. for recovering the ferroelectric layer characteristic.

11. The method of claim 10, wherein the second heat treatment in the presence of N₂ is carried out for about 30 minutes.

12. The method of claim 7, wherein the step d) is carried out in a presence of an inert gas and, after the step f), further comprising the step of carrying out a second heat treatment in a presence of N₂ gas at a temperature ranging from 450° C. to 700° C.

13. The method of claim 12, wherein the second heat treatment is carried out for about 30 minutes.
